(19) United States
(12) Patent Application Publication
(10) Pub. No.: US 2009/0317673 A1
(43) Pub. Date: Dec. 24, 2009

(54) Current collector, fuel cell stack, and fuel cell power generation system

(75) Inventors: Hye-Yeon Cha, Yongin-si (KR); Young-Soo Oh, Seongnam-si (KR); Jae-Hyuk Jang, Seoul (KR); Sung-Hen Kim, Suwon-si (KR); Craig Matthew Miesse, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD, Suwon (KR)

(21) Appl. No.: 12/457,591

(22) Filed: Jun. 16, 2009

(30) Foreign Application Priority Data
Jun. 24, 2008 (KR) 10-2008-0059451

(51) Int. Cl. H01M 8/18; H01M 2/32; H01M 8/10; B05D 5/12; C23C 14/00

(52) U.S. Cl. 429/19; 429/34; 429/30; 427/115; 204/192.15

(57) ABSTRACT

A current collector, a method of manufacturing the current collector, a fuel cell stack, and a fuel cell power generation system are disclosed. The current collector for collecting an electric current generated in a fuel cell can include: a substrate; a collector pattern, which contains a conductive material, formed on one side of the substrate; and a corrosion-resistant metal layer, which is coated over all of the surfaces of the collector pattern, including the surface facing the substrate. This current collector can be utilized to prevent corrosion during the operation of the fuel cell, as well as to increase the life span of the fuel cell, without forming the entire configuration with an expensive corrosion-resistant metal.

### CROSS-REFERENCE TO RELATED APPLICATIONS

This application claims the benefit of Korean Patent Application No. 10-2008-0059451 filed with the Korean Intellectual Property Office on Jun. 24, 2008, the disclosure of which is incorporated herein by reference in its entirety.

### BACKGROUND

1. Technical Field

The present invention relates to a current collector and to a method of manufacturing the current collector, as well as to a fuel cell stack and a fuel cell power generation system.

2. Description of the Related Art

The fuel cell power generation system is a system for generating electricity by electrochemically reacting a hydrogen-containing fuel, such as methanol, etc., with an oxidizing gas, such as air, etc. The fuel cell power generation system is regarded as a clean energy source for satisfying the increasing demands for power consumption while providing a solution to environmental problems resulting from the use of fossil energy.

A fuel cell power generation system generally includes a fuel cell stack, in which a multiple number of unit cells for generating electricity are stacked over one another. The basic structure of a stack may include multiple unit cells stacked between end plates and fastened together with bolts and nuts. A unit cell may be composed of a membrane electrode assembly (MEA) and separators, or bipolar plates, which are positioned on both sides of the membrane electrode assembly and in which fluid channels are formed.

The operations of a bipolar plate may include supplying the hydrogen-containing fuel and oxygen to the fuel electrode and air electrode, respectively, as well as discharging the carbon dioxide and water generated at the fuel electrode and air electrode, respectively, to the outside.

Here, current collectors may be provided, for collecting the electricity generated by the membrane electrode assembly, between the bipolar plates positioned at the outermost ends of the group of unit cells (hereinafter referred to as “outermost bipolar plates”) and the end plates. In addition to collecting electricity, a current collector may also provide reinforcement against the brittleness of the outermost bipolar plates when fastening the bolts and nuts.

In order to render low electrical resistance, a current collector may be made from a metallic material such as stainless steel. Since there will be chemical reactions occurring within the fuel cell, it may be advantageous to select a material that is resistant to corrosion, so that the life span of the fuel cell may be increased. However, corrosion-resistant metals are generally precious metals, such as platinum and gold, and therefore the use of metals that provide high resistant to corrosion may greatly increase the cost of the fuel cell.

### SUMMARY

An aspect of the invention provides a current collector that collects electricity generated by electrochemical reactions between hydrogen and oxygen, as well as a fuel cell power generation system equipped with the current collector.

Another aspect of the invention provides a current collector for collecting an electric current generated in a fuel cell that includes: a substrate; a collector pattern, which contains a conductive material, formed on one side of the substrate; and a corrosion-resistant metal layer, which is coated over all of the surfaces of the collector pattern, including the surface facing the substrate.

Copper (Cu) or nickel (Ni) can be used for the conductive material, while a material containing gold (Au) or platinum (Pt) can be used for the corrosion-resistant metal layer. The substrate can be a flexible substrate, which can be such that is made from a material containing polyimide.

Still another aspect of the invention provides a method of manufacturing a current collector for collecting an electric current generated in a fuel cell by forming a collector pattern. The method includes: selectively applying a corrosion-resistant metal over a substrate; forming a collector pattern by plating a conductive material over the corrosion-resistant metal; and coating a corrosion-resistant metal over a surface of the collector pattern.

The operation of applying the corrosion-resistant metal can be performed using a sputtering method or an ion plating method.

Forming the collector pattern can include: forming a plating resist, in which an aperture is formed, over the substrate; forming the collector pattern over the corrosion-resistant metal exposed through the aperture using a conductive material; and removing the remaining plating resist.

The operation of coating the corrosion-resistant metal can be performed using any of a sputtering method, an ion plating method, and a chemical vapor deposition method.

Copper (Cu) or nickel (Ni) can be used for the conductive material, while a material containing gold (Au) or platinum (Pt) can be used for the corrosion-resistant metal layer. The substrate can be a flexible substrate, which can be such that is made from a material containing polyimide.

Yet another aspect of the invention provides a fuel cell stack that includes: a pair of flat end plates, a membrane electrode assembly (MEA), which is positioned between the pair of end plates, and which includes an electrolyte layer, and an air electrode and a fuel electrode coupled to either side of the electrolyte layer, respectively; and a current collector, which collects the electric current generated in the membrane electrode assembly, where the current collector may include: a substrate; a collector pattern, which contains a conductive material, formed on one side of the substrate; and a corrosion-resistant metal layer, which is coated over all of the surfaces of the collector pattern, including the surface facing the substrate.

The substrate can be a flexible substrate, especially a substrate made from a material containing polyimide.

The collector pattern can also be formed on the surface of an end plate facing the membrane electrode assembly.

Copper (Cu) or nickel (Ni) can be used for the conductive material, while a material containing gold (Au) or platinum (Pt) can be used for the corrosion-resistant metal layer.

A multiple number of membrane electrode assemblies can be included, where the membrane electrode assemblies may be stacked in multiple layers with a bipolar plate interposed between each of the membrane electrode assemblies.

A further aspect of the invention provides a fuel cell power generation system that includes: a fuel cell stack; a fuel supply unit, which may supply a fuel containing hydrogen to the fuel cell stack; and an air supply unit, which may supply air to the fuel cell stack. The fuel cell stack can include: a pair of flat end plates, a membrane electrode assembly (MEA), which is positioned between the pair of end plates, and which includes an electrolyte layer, and an air electrode and a fuel electrode coupled to either side of the electrolyte layer, respectively; and a current collector, which collects the electric current generated in the membrane electrode assembly, where the current collector may include: a substrate; a collector pattern, which contains a conductive material, formed on one side of the substrate; and a corrosion-resistant metal layer, which is coated over all of the surfaces of the collector pattern, including the surface facing the substrate.

The substrate can be a flexible substrate, especially a substrate made from a material containing polyimide.

The collector pattern can also be formed on the surface of an end plate facing the membrane electrode assembly.

Copper (Cu) or nickel (Ni) can be used for the conductive material, while a material containing gold (Au) or platinum (Pt) can be used for the corrosion-resistant metal layer.

A multiple number of membrane electrode assemblies can be included, where the membrane electrode assemblies may be stacked in multiple layers with a bipolar plate interposed between each of the membrane electrode assemblies.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross sectional view of a current collector according to the related art.

FIG. 2 is a cross sectional view illustrating a current collector according to an aspect of the invention.

FIG. 3 is a flowchart illustrating a method of manufacturing a current collector according to another aspect of the invention.

FIG. 4, FIG. 5, and FIG. 6 are cross sectional views representing a method of manufacturing a current collector according to another aspect of the invention.

FIG. 7 is a cross sectional view illustrating a fuel cell stack intended for use in a fuel cell power generation system according to yet another aspect of the invention.

FIG. 8 is a schematic diagram illustrating a fuel cell power generation system according to still another aspect of the invention.

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Certain embodiments of the invention will now be described below in more detail with reference to the accompanying drawings. Those components that are the same or are in correspondence are rendered the same reference numeral regardless of the figure number, and redundant explanations are omitted.

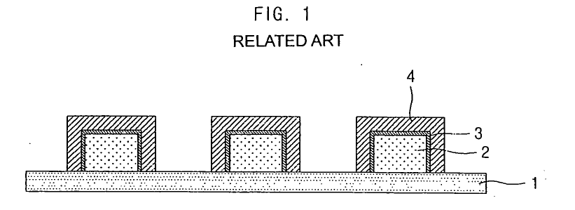

FIG. 1 is a cross sectional view of a current collector according to the related art. In the related art, a current collector may be formed by forming a collector pattern 2 over a substrate 1 with copper, forming a nickel layer 3 over the surfaces, and then applying gold plating 4. The resulting configuration, as depicted in FIG. 1, may be used to collect electrical energy generated in a fuel cell.

In this current collector, however, the gold plating layer 4 may be incomplete at the interface contacting the substrate 1, and as small gaps occur, there is a risk that the collector pattern 2 made of copper may corrode. If the substrate is made from a flexible material, in particular, the bending of the flexible substrate can increase the likelihood of gaps occurring between the gold plating 4 and the substrate 1, making it difficult to completely prevent corrosion.

Thus, in order to prevent reductions in power generation efficiency caused by corrosion, certain aspects of the invention provide a current collector, as well as a fuel cell power generation system and a method of manufacturing the current collector, which provide increased corrosion resistance.

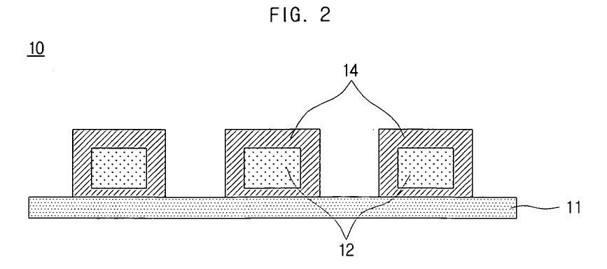

FIG. 2 is a cross sectional view illustrating a current collector according to an aspect of the invention, in which a substrate 11, a collector pattern 12, and a corrosion-resistant metal layer 14.

The surfaces of the collector pattern 12 formed over the substrate 11, including the surface that is in contact with the substrate 11, can be coated with a corrosion-resistant metal layer 14. With the corrosion-resistant metal layer 14 coated over the surface touching the substrate 11, the collector pattern 12 may be protected from corrosion.

A metal resistant to corrosion, such as platinum (Pt) and gold (Au), etc., can be used for the corrosion-resistant metal, while a metal that has low electrical resistance and relatively low cost, such as copper (Cu) and nickel (Ni), can be used for the collector pattern 12. The substrate 11 can be a flexible substrate and can be made from a material that includes polyimide.

It is also possible to form the collector pattern directly on an end plate of the fuel cell or on the outermost bipolar plate. In such cases also, the corrosion-resistant metal layer can be coated over the surfaces of the collector pattern that are in contact with the end plate or outermost bipolar plate, to prevent corrosion in the collector pattern.

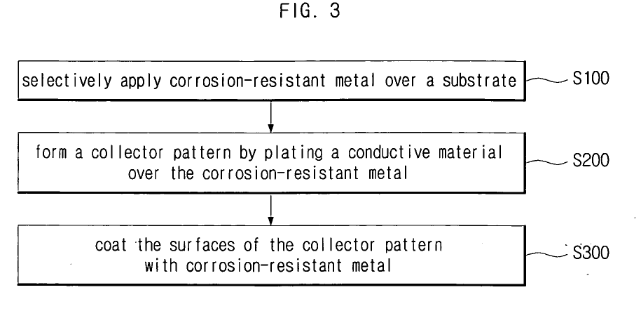

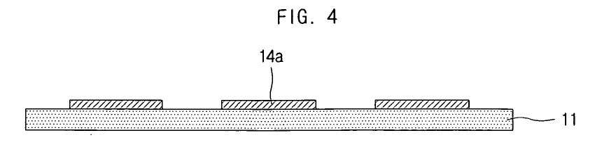

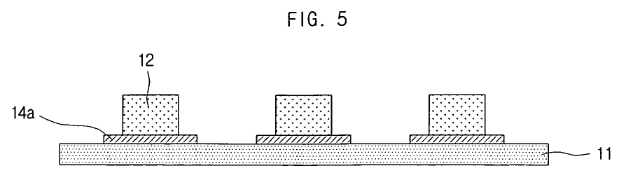

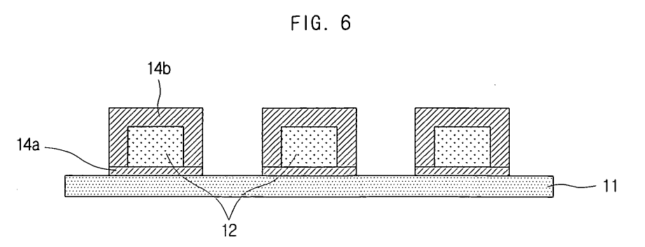

FIG. 3 is a flowchart illustrating a method of manufacturing a current collector according to another aspect of the invention, and FIG. 4 through FIG. 6 are cross sectional views representing a method of manufacturing a current collector according to another aspect of the invention. In FIGS. 4 to 6, there are illustrated a substrate 11, a collector pattern 12, and corrosion-resistant metal 14a, 14b.

First, the corrosion-resistant metal 14a can be selectively applied onto the substrate 11 (S100). The corrosion-resistant metal 14a can be applied in correspondence with the collector pattern. A flexible substrate can be used for the substrate 11, where a material containing polyimide may be used. A metal resistant to corrosion, such as platinum (Pt) and gold (Au), etc., can be used for the corrosion-resistant metal 14a.

The operation of applying the corrosion-resistant metal 14a may generally be performed using a method of sputtering or of ion plating.

A sputtering method may involve forming glow discharge using an inert gas (usually Ar, Kr, Xe, etc.) in a vacuum environment, to have positive ions collide into a negatively biased target, so that the atoms of the target may be ejected due to the transfer of kinetic energy. The ejected atoms may move freely within the vacuum chamber, and the atoms reaching the substrate may form a deposit layer. The sputtered atoms may retain relatively high kinetic energy, which allows surface diffusion to thermodynamically stable positions when the atoms form a deposit layer over the surface of the substrate, so that a film having an elaborate composition may be formed.

Ion plating can be regarded as a hybrid technique, combining the fast deposition speed provided by evaporation and the ability to form elaborate thin film compositions and chemical compounds provided by sputtering. That is, an ion plating method may include an evaporating source as used in evaporation, and employ a plasma as used in sputtering, to partially ionize the evaporated atoms (and the reactive gases if necessary) to increase kinetic energy and reactivity.

Sputtering methods and ion plating methods may be collectively referred to as physical vapor deposition (PVD) methods. By using a sputtering or an ion plating method, a thin film of corrosion-resistant metal 14a can be deposited over the substrate 11, as illustrated in FIG. 4.

Next, a conductive material can be plated over the corrosion-resistant metal 14a to form a collector pattern 12 (S200). The collector pattern 12 is intended to collect the electric current generated in the membrane electrode assembly (MEA) and supply electrical power to an external device, and thus can be made from a material high in electrical conductivity. For example, a metal that has low electrical resistance and relatively low cost, such as copper (Cu) and nickel (Ni), can be used.

The forming of the collector pattern can be performed by procedures of forming a plating resist having an aperture over the substrate, forming the collector pattern using a conductive material over the corrosion-resistant metal exposed through the aperture; and removing the remaining plating resist.

The plating resist can be formed by performing photolithography processes. The photolithography processes may include selectively irradiating certain rays through a mask, in which a desired pattern is formed, onto a photosensitive material, which undergoes chemical reactions and changes properties when irradiated with the rays, to form a plating resist that has the same pattern as the pattern in the mask. The photolithography processes may include a coating process for applying the photosensitive material, an exposure process for selectively irradiating rays using a mask, and a developing process for removing the irradiated portions of the photosensitive material using a developer to form the plating resist.

After the photolithography processes, the conductive material can be electroplated onto the corrosion-resistant metal exposed at the surface, and the remaining photosensitive material can be removed to form the collector pattern 12. The portions for plating the conductive material can be made smaller than the portions of corrosion-resistant metal 14a, so that the collector pattern 12 may be formed without overstepping the boundaries of the corrosion-resistant metal 14a, as illustrated in FIG. 5.

Next, the corrosion-resistant metal 14b can be coated over the surfaces of the collector pattern 12 (S300).

The operation of coating the corrosion-resistant metal 14b can be performed by any one of a sputtering method, an ion plating method, and a chemical vapor deposition method. As sputtering and ion plating have been described above, a description will be provided as follows on chemical vapor deposition.

Chemical vapor deposition involves introducing a reactive gas, which contains the material desired for deposition, into the reactor chamber and having the gas thermally decompose at the surfaces of the heated substrate to deposit the desired material. Types of chemical vapor deposition include, for example, thermal chemical vapor deposition, in which the reactive gas undergoes thermal decomposition at high temperatures, and plasma chemical vapor deposition, in which the reactive gas is decomposed by plasma.

As the collector pattern 12 may be smaller than the corrosion-resistant metal 14a formed on the substrate 11, the corrosion-resistant metal 14b can be coated over the surfaces of the collector pattern to completely coat the collector pattern 12 with corrosion-resistant metal 14a, 14b, as illustrated in FIG. 6. If the same composition is used for the corrosion-resistant metal 14a and the corrosion-resistant metal 14b, the coating around the collector pattern 12 can form an integrated shape, with no gaps at the connecting portions, so that the collector pattern 12 may be protected from corrosion.

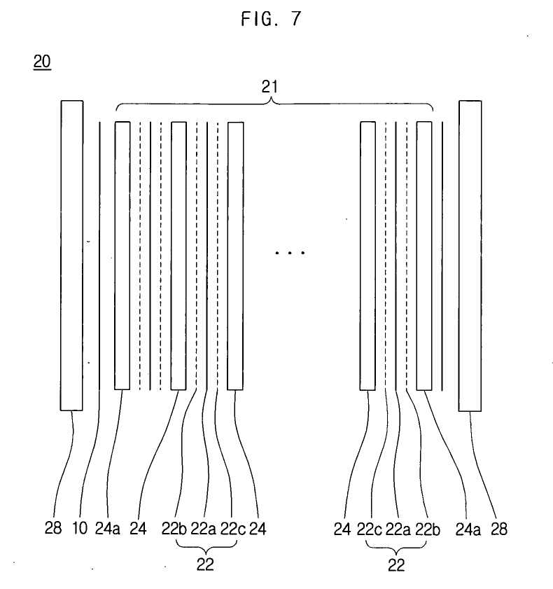

FIG. 7 is a cross sectional view illustrating a fuel cell stack 20 in a fuel cell power generation system according to yet another aspect of the invention. In FIG. 7, there are illustrated membrane electrode assemblies 22, an electric generator unit 21, end plates 28, and membrane electrode assemblies (MEA) 22, which may each include an electrolyte layer 22a that allows selective permeation of hydrogen ions, and a fuel electrode and an air electrode 22b, 22c provided on either side of the electrolyte layer 22a. A membrane electrode assembly 22 can serve to actually generate electricity by reacting the fuel with a catalyst.

The chemical reactions occurring at the electrodes, for an example case of a direct methanol fuel cell (DMFC), can be represented as follows.

Fuel Electrode: CH₃OH⁻+H₂O→CO₂+6H⁺+6e⁻ <Equation 1>

Air Electrode: (3/2)O₂+6H⁺+6e⁻→3H₂O <Equation 2>

Overall Reaction: CH₃OH+(3/2)O₂→2H₂O+CO₂ <Equation 3>

The chemical reactions represented above may be used to generate electricity, where water may be produced at the air electrode. As described above, the chemical reactions presented above are for examples in which a direct methanol fuel cell is used, and it is to be appreciated that the chemical reaction occurring at each electrode may vary according to the type of fuel cell.

The fuel cell stack 20 can include bipolar plates 24 positioned between adjacent membrane electrode assemblies 22 to supply hydrogen and oxygen to the fuel electrodes 22b and air electrodes 22c of the membrane electrode assemblies 22, respectively.

The electric generator unit 21 refers to the structure in which multiple membrane electrode assemblies 22 are stacked together with bipolar plates 24 interposed in-between.

The structure of the fuel cell stack 20 can be secured by the current collectors 10 and end plates 28 provided in order on the outer sides of the bipolar plates positioned at both ends of the electric generator unit 21, i.e. the outermost bipolar plates 24a.

In this embodiment, a current collector 10 can include a collector pattern coated with corrosion-resistant metal. As already described above, a collector pattern coated with corrosion-resistant metal can be formed directly on an end plate 28 or on an outermost bipolar plate 24a to substitute a current collector 10. The current collectors 10 and the collector pattern have already been described above with reference to the previously disclosed embodiment, and thus redundant descriptions will be omitted.

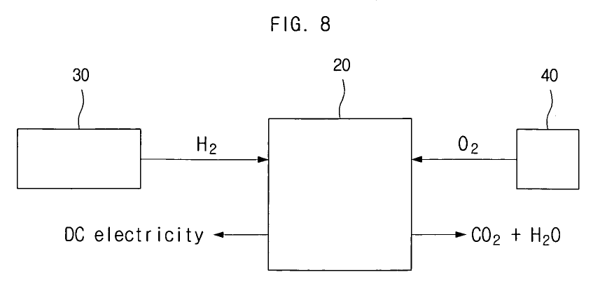

Using a fuel cell stack such as that described above, a fuel cell power generation system can be provided. FIG. 8 is a schematic diagram illustrating a fuel cell power generation system according to still another aspect of the invention, in which a fuel cell stack 20, a fuel supply unit 30, and an air supply unit 40 are illustrated.

The fuel supply unit 30 can supply a fuel containing hydrogen to the fuel cell stack 20, while the air supply unit 40 can supply oxygen to the fuel cell stack 20. A circuit unit may also be included, which may be electrically connected with the current collector of the fuel cell stack 20 to serve as a channel that allows movement for electrical charges generated in the fuel cell stack 20.

The structure of the fuel cell stack 20 used in the fuel cell power generation system according to this embodiment may be substantially the same as that described above, and thus redundant descriptions will be omitted.

As set forth above, certain embodiments of the invention can be utilized to prevent corrosion in the current collectors while the fuel cell is operated, and thereby increase the life span of the fuel cell, without forming the entire configuration with an expensive corrosion-resistant metal.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

Many embodiments other than those set forth above can be found in the appended claims.

What is claimed is:

1. A current collector for collecting an electric current generated in a fuel cell, the current collector comprising:
a substrate;
a collector pattern formed on one side of the substrate, the collector pattern containing a conductive material; and
a corrosion-resistant metal layer coated over all surfaces of the collector pattern including a surface facing the substrate.

2. The current collector of claim 1, wherein the conductive material is copper (Cu) or nickel (Ni).

3. The current collector of claim 1, wherein the corrosion-resistant metal layer is made from a material containing gold (Au) or platinum (Pt).

4. The current collector of claim 1, wherein the substrate is flexible.

5. The current collector of claim 4, wherein the substrate is made from a material containing polyimide.

6. A method of manufacturing a current collector for collecting an electric current generated in a fuel cell by forming a collector pattern, the method comprising:
selectively applying a corrosion-resistant metal over a substrate;
forming a collector pattern by plating a conductive material over the corrosion-resistant metal; and
coating a corrosion-resistant metal over a surface of the collector pattern.

7. The method of claim 6, wherein the applying of the corrosion-resistant metal is performed by sputtering or ion plating.

8. The method of claim 6, wherein the forming of the collector pattern comprises:
forming a plating resist over the substrate, the plating resist having an aperture formed therein;
forming the collector pattern with a conductive material over the corrosion-resistant metal exposed through the aperture; and
removing the remaining plating resist.

9. The method of claim 6, wherein the coating of the corrosion-resistant metal is performed by any one of sputtering, ion plating, and chemical vapor deposition.

10. The method of claim 6, wherein the conductive material is copper (Cu) or nickel (Ni).

11. The method of claim 6, wherein the corrosion-resistant metal layer is made from a material containing gold (Au) or platinum (Pt).

12. The method of claim 6, wherein the substrate is flexible.

13. The method of claim 6, wherein the substrate is made from a material containing polyimide.

14. A fuel cell stack comprising:
a pair of flat end plates,
a membrane electrode assembly (MEA) interposed between the pair of end plates, the membrane electrode assembly comprising an electrolyte layer, and an air electrode and a fuel electrode coupled to either side of the electrolyte layer, respectively; and
a current collector configured to collect an electric current generated in the membrane electrode assembly, the current collector comprising:
a substrate;
a collector pattern formed on one side of the substrate, the collector pattern containing a conductive material; and
a corrosion-resistant metal layer coated over all surfaces of the collector pattern including a surface of the collector pattern facing the substrate.

15. The fuel cell stack of claim 14, wherein the substrate is flexible.

16. The fuel cell stack of claim 15, wherein the substrate is made from a material containing polyimide.

17. The fuel cell stack of claim 14, wherein the conductive material is copper (Cu) or nickel (Ni).

18. The fuel cell stack of claim 14, wherein the corrosion-resistant metal layer is made from a material containing gold (Au) or platinum (Pt).

19. The fuel cell stack of claim 14, comprising a plurality of the membrane electrode assemblies,
wherein the membrane electrode assemblies are stacked with a bipolar plate interposed between each of the membrane electrode assemblies.

20. A fuel cell stack comprising:
a pair of flat end plates,
a membrane electrode assembly (MEA) interposed between the pair of end plates, the membrane electrode assembly comprising an electrolyte layer, and an air electrode and a fuel electrode coupled to either side of the electrolyte layer, respectively;
a collector pattern formed on a surface of the end plates facing the membrane electrode assembly, the collector pattern containing a conductive material; and
a corrosion-resistant metal layer coated over all surfaces of the collector pattern including a surface of the collector pattern facing the substrate.

21. The fuel cell stack of claim 20, wherein the conductive material is copper (Cu) or nickel (Ni).

22. The fuel cell stack of claim 20, wherein the corrosion-resistant metal layer is made from a material containing gold (Au) or platinum (Pt).

23. The fuel cell stack of claim 20, comprising a plurality of the membrane electrode assemblies,
wherein the membrane electrode assemblies are stacked with a bipolar plate interposed between each of the membrane electrode assemblies.

24. A fuel cell power generation system comprising:
a fuel cell stack;
a fuel supply unit configured to supply a fuel containing hydrogen to the fuel cell stack; and
an air supply unit configured to supply air to the fuel cell stack,
wherein the fuel cell stack comprises:
a pair of flat end plates,
a membrane electrode assembly (MEA) interposed between the pair of end plates, the membrane electrode assembly comprising an electrolyte layer, and an air electrode and a fuel electrode coupled to either side of the electrolyte layer, respectively; and
a current collector configured to collect an electric current generated in the membrane electrode assembly, the current collector comprising:
a substrate;
a collector pattern formed on one side of the substrate, the collector pattern containing a conductive material; and
a corrosion-resistant metal layer coated over all surfaces of the collector pattern including a surface of the collector pattern facing the substrate.

25. The fuel cell power generation system of claim 24, wherein the substrate is flexible.

26. The fuel cell power generation system of claim 25, wherein the substrate is made from a material containing polyimide.

27. The fuel cell power generation system of claim 24, wherein the conductive material is copper (Cu) or nickel (Ni).

28. The fuel cell power generation system of claim 24, wherein the corrosion-resistant metal layer is made from a material containing gold (Au) or platinum (Pt).

29. The fuel cell power generation system of claim 24, comprising a plurality of the membrane electrode assemblies,
wherein the membrane electrode assemblies are stacked with a bipolar plate interposed between each of the membrane electrode assemblies.

30. A fuel cell power generation system comprising:
a fuel cell stack;
a fuel supply unit configured to supply a fuel containing hydrogen to the fuel cell stack; and
an air supply unit configured to supply air to the fuel cell stack,
wherein the fuel cell stack comprises:
a pair of flat end plates,
a membrane electrode assembly (MEA) interposed between the pair of end plates, the membrane electrode assembly comprising an electrolyte layer, and an air electrode and a fuel electrode coupled to either side of the electrolyte layer, respectively;
a collector pattern formed on a surface of the end plates facing the membrane electrode assembly, the collector pattern containing a conductive material; and
a corrosion-resistant metal layer coated over all surfaces of the collector pattern including a surface of the collector pattern facing the substrate.

31. The fuel cell power generation system of claim 30, wherein the conductive material is copper (Cu) or nickel (Ni).

32. The fuel cell power generation system of claim 30, wherein the corrosion-resistant metal layer is made from a material containing gold (Au) or platinum (Pt).

33. The fuel cell power generation system of claim 30, comprising a plurality of the membrane electrode assemblies,
wherein the membrane electrode assemblies are stacked with a bipolar plate interposed between each of the membrane electrode assemblies.
